(19) United States
(12) Patent Application Publication
(10) Pub. No.: US 2024/0080062 A1
(43) Pub. Date: Mar. 7, 2024

(54) INTERNAL TRANSMIT/RECEIVE SWITCH WITH HARDWARE REUSE

(71) Applicant: QUALCOMM Incorporated, San Diego, CA (US)

(72) Inventors: Cheng-Han WANG, San Jose, CA (US); Yi ZENG, San Jose, CA (US); Takahide NISHIO, San Jose, CA (US); Chan Hong PARK, San Jose, CA (US); Emanuele LOPELLI, Laguna Niguel, CA (US); Liang ZHAO, Saratoga, CA (US)

(21) Appl. No.: 17/939,409

(22) Filed: Sep. 7, 2022

(51) Int. Cl. H04B 1/44; H03F 3/24

(52) U.S. Cl. CPC H04B 1/44; H03F 3/245; H03F 2200/294; H03F 2200/451

(57) ABSTRACT

An apparatus includes a low-noise amplifier having an input and an output, a first switch coupled between the input of the low-noise amplifier and the output of the low-noise amplifier, and a transformer including a first inductor and a second inductor, wherein the first inductor is coupled to the output of the low-noise amplifier. The apparatus also includes a power amplifier having an input and an output, and a switching circuit coupled between the output of the power amplifier and the second inductor.

### BACKGROUND

### Field

Aspects of the present disclosure relate generally to wireless communications, and, more particularly, to an interface circuit.

### BACKGROUND

A wireless device includes a transceiver for transmitting and receiving radio frequency (RF) signals via one or more antennas. The transceiver may include a power amplifier (PA) configured to amplify an RF signal for transmission via an antenna and a low-noise amplifier (LNA) configured to amplify an RF signal received by the antenna. The transceiver may also include an interface circuit configured to couple the PA and the LNA to the antenna. The interface circuit may include one or more switches for selectively coupling the PA and the LNA to the antenna. For example, the one or more switches may couple the PA to the antenna in a transmit mode and couple the LNA to the antenna in a receive mode.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to an apparatus. The apparatus includes a low-noise amplifier having an input and an output, a first switch coupled between the input of the low-noise amplifier and the output of the low-noise amplifier, and a transformer including a first inductor and a second inductor, wherein the first inductor is coupled to the output of the low-noise amplifier. The apparatus also includes a power amplifier having an input and an output, and a switching circuit coupled between the output of the power amplifier and the second inductor.

A second aspect relates to an apparatus. The apparatus includes a low-noise amplifier having an input and an output, and a first switch coupled between the input of the low-noise amplifier and the output of the low-noise amplifier. The apparatus also includes transformer including a first inductor, a second inductor, a third inductor, one or more first inductor switches coupled in series with the second inductor, and one or more second inductor switches coupled is series with the third inductor, wherein the first inductor is coupled to the output of the low-noise amplifier. The apparatus also includes a power amplifier having an input and an output, wherein the output of the power amplifier is coupled to the third inductor.

A third aspect relates to a method for operating a wireless device. The wireless device includes a low-noise amplifier having an input and output, a switch coupled between the input of the low-noise amplifier and the output of the low-noise amplifier, and a power amplifier. The method includes, in a receive mode, opening the switch, receiving a first radio frequency (RF) signal at the input of the low-noise amplifier from an antenna, and amplifying the first RF signal using the low-noise amplifier into an amplified RF signal. The method also includes, in a transmit mode, closing the switch, and routing a second RF signal from the power amplifier to the antenna through the switch.

A fourth aspect relates to an apparatus. The apparatus includes a low-noise amplifier having an input and an output, a switch coupled between the input of the low-noise amplifier and the output of the low-noise amplifier, and a power amplifier. The apparatus also includes means for opening the switch in a receive mode, and means for inputting a first radio frequency (RF) signal from an antenna to the input of the low-noise amplifier in the receive mode. The apparatus also includes means for closing the switch in a transmit mode, and means for routing a second RF signal from the power amplifier to the antenna through the switch in the transmit mode.

### BRIEF DESCRIPTION OF THE DRAWINGS

FIG. 1 shows an example of a wireless device including a power amplifier, a low-noise amplifier, an antenna, and a switching circuit according to certain aspects of the present disclosure.

FIG. 2 shows an exemplary implementation of the switching circuit according to certain aspects of the present disclosure.

FIG. 3 shows an example of a wireless device including a power amplifier, a low-noise amplifier, a transformer, and a switching circuit according to certain aspects of the present disclosure.

FIG. 4A shows an example of the wireless device in a receive mode according to certain aspects of the present disclosure.

FIG. 4B shows an example of the wireless device including a transconductor in the receive mode according to certain aspects of the present disclosure.

FIG. 5A shows an example of the wireless device in a transmit mode according to certain aspects of the present disclosure.

FIG. 5B shows an example of the wireless device including the transconductor in the transmit mode according to certain aspects of the present disclosure.

FIG. 6 shows an example of the wireless device further including a resistor and one or more capacitors according to certain aspects of the present disclosure.

FIG. 7 shows another example of the wireless device in the receive mode according to certain aspects of the present disclosure.

FIG. 8 shows another example of the wireless device in the transmit mode according to certain aspects of the present disclosure.

FIG. 9 shows an exemplary implementation of the low-noise amplifier in the receive mode according to certain aspects of the present disclosure.

FIG. 10 shows an exemplary implementation of the low-noise amplifier in the transmit mode according to certain aspects of the present disclosure.

FIG. 11 shows an example of the wireless device including a bias circuit according to certain aspects of the present disclosure.

FIG. 12 shows an exemplary implementation of an input matching circuit in the receive mode according to certain aspects of the present disclosure.

FIG. 13 shows an exemplary implementation of the input matching circuit in the transmit mode according to certain aspects of the present disclosure.

FIG. 14 shows an exemplary implementation of the transformer in the receive mode according to certain aspects of the present disclosure.

FIG. 15 shows an exemplary implementation of the transformer in the transmit mode according to certain aspects of the present disclosure.

FIG. 16 shows an example of the power amplifier transmitting via a first antenna according to certain aspects of the present disclosure.

FIG. 17 shows an example of the power amplifier transmitting via a second antenna according to certain aspects of the present disclosure.

FIG. 18 shows an example of a switching circuit configured to switch the power amplifier between a first transformer and a second transformer according to certain aspects of the present disclosure.

FIG. 19 is a diagram of an environment including an electronic device that includes a transceiver according to certain aspects of the present disclosure.

FIG. 20 is a flowchart illustrating an exemplary method for operating a wireless device according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

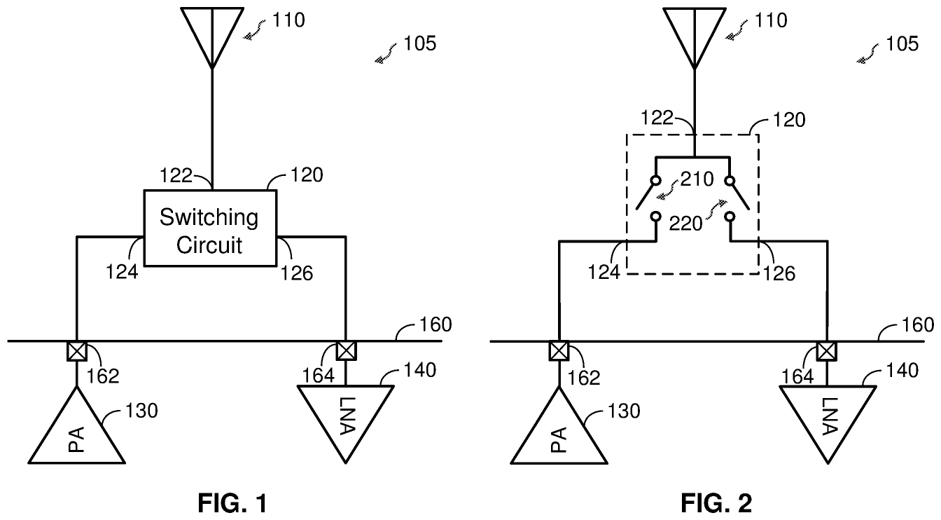

FIG. 1 shows an example of a wireless device 105 according to certain aspects. The wireless device 105 includes an antenna 110, a power amplifier (PA) 130, a low-noise amplifier (LNA) 140, and a switching circuit 120 according to certain aspects. The PA 130 and the LNA 140 may be part of a transceiver configured to transmit and receive radio frequency (RF) signals via one or more antennas including the antenna 110. The PA 130 is configured to amplify an RF signal for transmission via the antenna 110 and the LNA 140 is configured to amplify an RF signal received by the antenna 110.

The switching circuit 120 acts as an interface circuit interfacing the PA 130 and the LNA 140 with the antenna 110. In the example in FIG. 1, the switching circuit 120 has a first terminal 122 coupled to the antenna 110, a second terminal 124 coupled to the output of the PA 110, and a third terminal 126 coupled to the input of the LNA 140. In certain aspects, the switching circuit 120 is configured to selectively couple the PA 130 and the LNA 140 to the antenna 110. For example, the switching circuit 120 may couple the PA 130 to the antenna 110 in a transmit mode and couple the LNA 140 to the antenna 110 in a receive mode.

FIG. 2 shows an example in which the switching circuit 120 includes a first switch 210 (also referred to as a transmit (TX) switch) coupled between the antenna 110 and the PA 130, and a second switch 220 (also referred to as a receive (RX) switch) coupled between the antenna 110 and the LNA 140. In this example, the first switch 210 is closed and the second switch 220 is open in the transmit mode, and the second switch 220 is closed and the first switch 210 is open in the receive mode. However, it is to be appreciated that the switching circuit 120 is not limited to this example.

Although one PA 130, one LNA 140, and one antenna 110 are shown in FIG. 1, it is to be appreciated that the wireless device 105 may include multiple PAs, multiple LNAs, and multiple antennas. For example, in some implementations, the switching circuit 120 may selectively couple the PA 130 to any one of multiple antennas in which the multiple antennas include the antenna 110. In this example, the multiple antennas may point in different directions. This allows the switching circuit 120 to switch the PA 130 between the multiple antennas to transmit signals in the different directions.

In the examples shown in FIG. 1 and FIG. 2, the PA 130 and the LNA 140 are integrated on a chip 160 (i.e., a die) and the switching circuit 120 is off chip (i.e., external to the chip 160). In these examples, the chip 160 includes a first pin 162 coupling the PA 130 to the switching circuit 120, and a second pin 164 coupling the LNA 140 to the switching circuit 120. A drawback of using an off-chip switching circuit for the switching circuit 120 is that the off-chip switching circuit adds costs to the wireless device 105. For the case where the switching circuit 120 and the chip 160 are mounted on a substrate (e.g., a printed circuit board), using an off-chip switching circuit for the switching circuit 120 may require adding one or more additional layers to the substrate. Accordingly, it is desirable to use internal TX/RX switches (i.e., switches integrated on the chip 160) to reduce costs.

In some designs using internal TX/RX switches, the chip includes one or more transformers configured to inductively (i.e., magnetically) couple RF signals from a PA to an antenna for transmission, and inductively (i.e., magnetically) couple RF signals received by the antenna to an LNA. In these designs, separate inductors or even separate transformers are used for transmitting and receiving RF signals, which may take up a large area of the chip. Also, in designs using an RX switch in the receive path to selectively couple the LNA to the antenna, signal losses in the RX switch may degrade RF signals in the receive path.

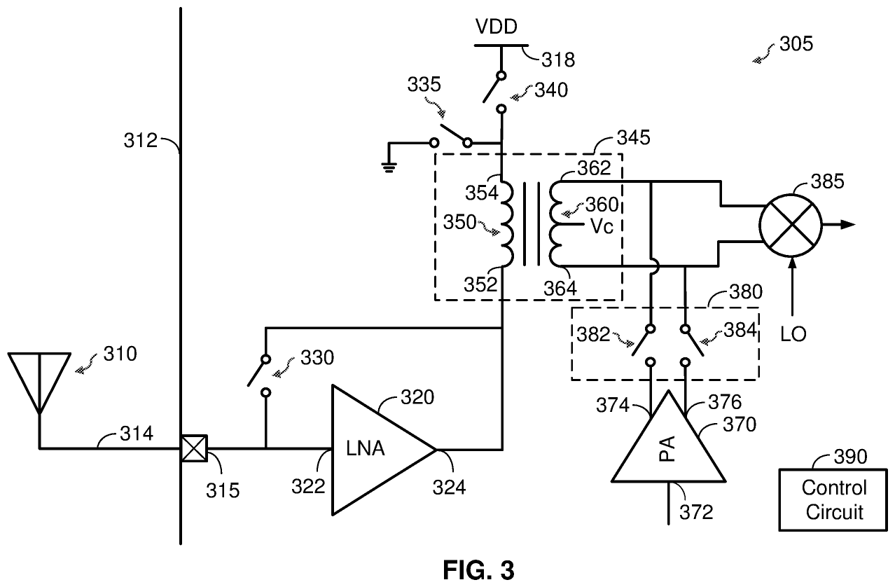

FIG. 3 shows an example of a wireless device 305 according to certain aspects. As discussed further below, the wireless device 305 addresses one or more of the problems discussed above. In this example, the wireless device 305 includes an antenna 310, a power amplifier (PA) 370, a low-noise amplifier (LNA) 320, a transformer 345, and a switching circuit 380 according to certain aspects. The PA 370 and the LNA 320 may be part of a transceiver configured to transmit and receive radio frequency (RF) signals via one or more antennas including the antenna 310. The PA 370 is configured to amplify an RF signal for transmission via the antenna 310 and the LNA 320 is configured to amplify an RF signal received by the antenna 310, as discussed further below.

In the example in FIG. 3, the PA 370, the LNA 320, the transformer 345, and the switching circuit 380 are integrated on a chip 312 (i.e., die). However, it is to be appreciated that the present disclosure is not limited to this example. In the example in FIG. 3, the antenna 310 is located off chip and may be coupled to the chip 312 via a transmission line 314. It is to be appreciated that the wireless device 305 may include one or more additional components (not shown) coupled between the antenna 310 and the chip 312 such as a filter (e.g., a bandpass filter).

In this example, the LNA 320 has an input 322 and an output 324. The input 322 of the LNA 320 is coupled to the antenna 310 via an input/output (I/O) pin 315 on the chip 312. The LNA 320 is configured to receive an RF signal from the antenna 310 at the input 322, amplify the received RF signal, and output the amplified RF signal at the output 324. In the example in FIG. 3, the receive path between the I/O pin 315 and the input 322 of the LNA 320 does not include an internal RX switch. This eliminates signal losses between the I/O pin 315 and the input 322 of the LNA 320 due to an internal RX switch. In the example shown in FIG. 3, the output 324 of the LNA 320 is a single-ended output. However, it is to be appreciated that the present disclosure is not limited to this example, and that the output 324 of the LNA 320 may be a differential output in some implementations.

In the example in FIG. 3, the PA 370 has an input 372 and a differential output, in which the differential output includes a first output 374 and a second output 376. In this example, the PA 370 is configured to receive an RF signal at the input 372 (e.g., from a mixer or another circuit), amplify the RF signal, and output the amplified RF signal at the differential output. In certain aspects, the PA 370 may be implemented with two or more amplifiers. The input 372 of the PA 370 may be a single-ended input or a differential input. In this example, the switching circuit 380 is coupled between the differential output of the PA 370 and the transformer 345. As discussed further below, the switching circuit 380 is configured to selectively couple the PA 370 to the transformer 345 under the control of a control circuit 390.

The transformer 345 includes a first inductor 350 and a second inductor 360 inductively (i.e., magnetically) coupled with each other. Each of the first inductor 350 and the second inductor 360 may be implemented with a coil inductor, a spiral inductor, a loop inductor, a slab inductor, or another type of inductor. It is to be appreciated that each of the first inductor 350 and the second inductor 360 may also be referred to as a winding or a coil. It is also to be appreciated that an inductor may be implemented with two or more inductors coupled in series and/or parallel.

The first inductor 350 has a first terminal 352 and a second terminal 354, in which the first terminal 352 is coupled to the output 324 of the LNA 320. The second inductor 360 has a first terminal 362 and a second terminal 364. The first terminal 362 and the second terminal 364 are coupled to the switching circuit 380. The first terminal 362 and the second terminal 364 may also be coupled to a mixer 385, which may be configured to frequency downconvert an RF signal from the LNA 320 to an intermediate frequency (IF) signal or a baseband signal, as discussed further below. The second inductor 360 may also include a center tap biased by voltage Vc, as shown in the example in FIG. 3. As discussed further below, the inductors 350 and 360 are both used for transmitting and receiving RF signals, which reduces area compared with designs that use separate inductors for transmitting and receiving RF signals.

In the example in FIG. 3, the wireless device 305 also includes a first switch 330 coupled between the I/O pin 315 and the first terminal 352 of the first inductor 350. As discussed further below, the first switch 330 is configured to provide a transmit path that bypasses the LNA 320 when the first switch 330 is closed (i.e., turned on).

The wireless device 305 also includes a second switch 335 coupled between ground and the second terminal 354 of the first inductor 350, and a third switch 340 coupled between a supply rail 318 and the second terminal 354 of the first inductor 350. The supply rail 318 is configured provide a supply voltage VDD (e.g., 0.8V) from a voltage source (not shown). As discussed further below, the second switch 335 and the third switch 340 are used to selectively couple the second terminal 354 of the first inductor 350 to ground or the supply rail 318.

The on/off states of the switches 330, 335, and 340 may be controlled by the control circuit 390. Each of the switches 330, 335, and 340 may be implemented with a respective transistor or another type of switch. For the example in which each of the switches 330, 335, and 340 is implemented with a respective transistor, the control circuit 390 may control the on/off state of each of the switches 330, 335, and 340 by controlling the gate voltage of the respective transistor. In one example, the second switch 335 may be implemented with an n-type field effect transistor (NFET), and the third switch 340 may be implemented with a p-type field effect transistor (PFET). However, it is to be appreciated that the second switch 335 and the third switch 340 are not limited to this example. For ease of illustration, the individual connections between the control circuit 390 and the switches 330, 335, and 340 are not explicitly shown in FIG. 3.

Exemplary operations of the wireless device 305 will now be described according to certain aspects.

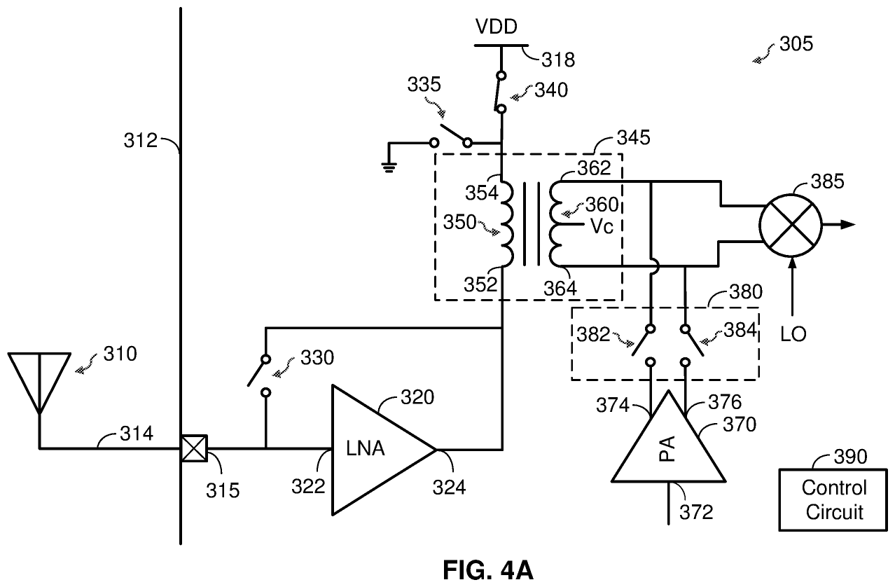

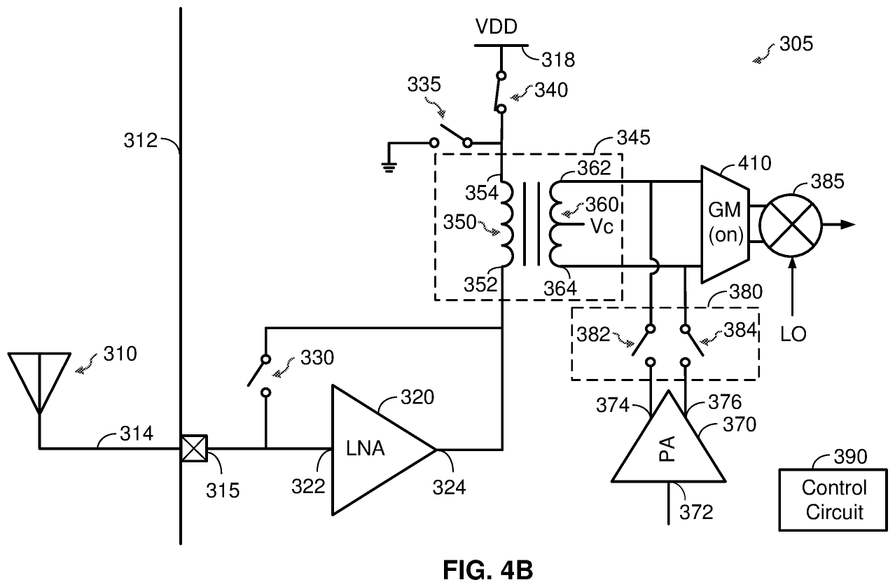

In certain aspects, the wireless device 305 is configured to receive RF signals via the antenna 310 in a receive mode. An example of the wireless device 305 in the receive mode is shown in FIG. 4A. In the receive mode, the control circuit 390 closes (i.e., turns on) the third switch 340, and opens (i.e., turns off) the first switch 330 and the second switch 335. In this mode, the LNA 320 is biased by the supply voltage VDD through the third switch 340. The control circuit 390 also causes the switching circuit 380 to decouple the PA 370 from the transformer 345.

In the receive mode, the LNA 320 receives an RF signal at the input 322 from the antenna 310, amplifies the RF signal, and outputs the amplified RF signal at the output 324. The transformer 345 inductively (i.e., magnetically) couples the amplified RF signal from the first inductor 350 to the second inductor 360. In the example in FIG. 4A, the transformer 345 also converts the amplified RF signal from a signal-ended signal at the first inductor 350 to a differential signal at the second inductor 360. However, it is to be appreciated that the present disclosure is not limited to this example.

From the second inductor 360, the amplified RF signal may be input to the mixer 385, which frequency downconverts the amplified RF signal to an IF signal or a baseband signal. For example, the mixer 385 may frequency downconvert the amplified RF signal by mixing the amplified RF signal with a local oscillator (LO) signal. The LO signal may be generated by a phase locked loop (PLL) or another type of local oscillator. The mixer 385 outputs the IF signal or baseband signal to other circuits (not shown) in the wireless device 305 for further processing. The other circuits may include a filter, another mixer, an amplifier, a phase shifter, and/or a baseband processor.

In some implementations, the mixer 385 may be coupled to the second inductor 360 of the transformer 345 via a transconductor 410 between the second inductor 360 and the mixer 385, as shown in FIG. 4B. In these implementations, the transconductor 410 may receive the differential RF signal from the second inductor 360 and convert the differential RF signal into a differential current for input to the mixer 385 or another circuit.

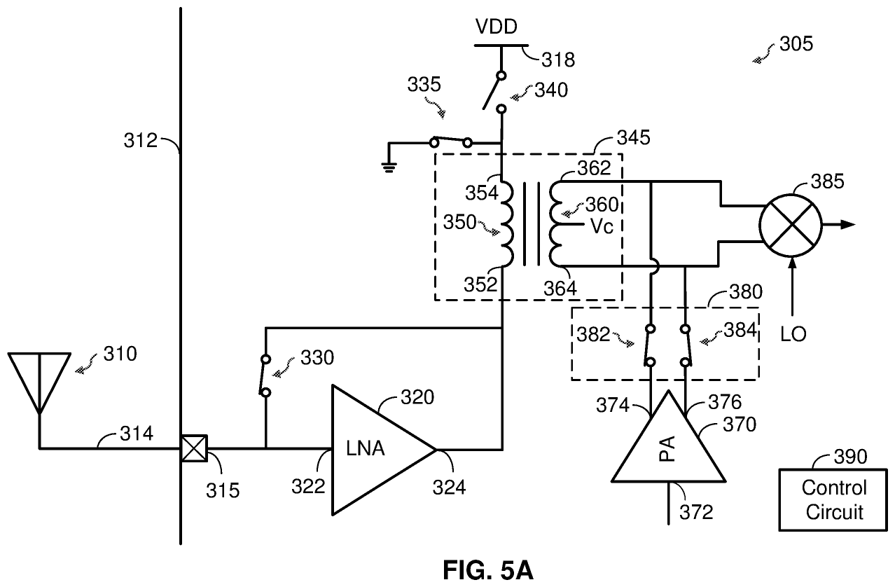

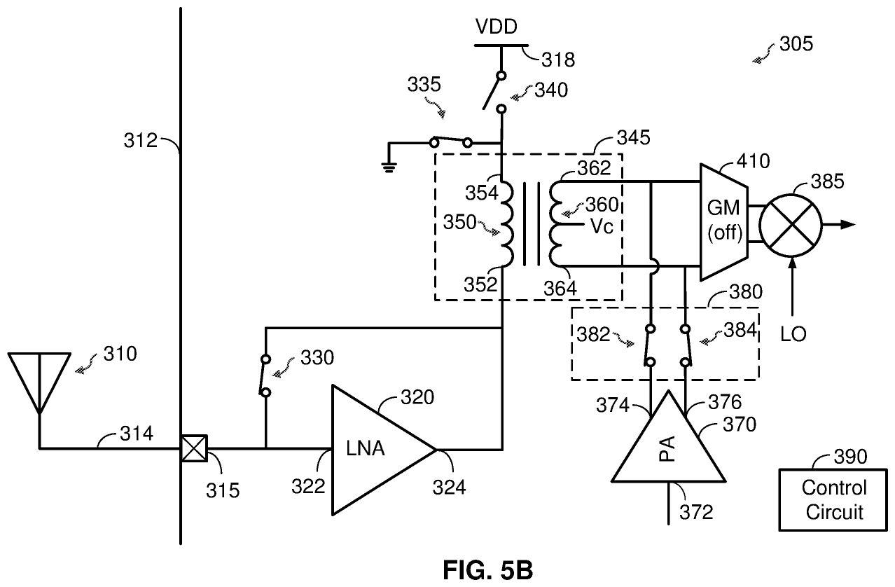

In certain aspects, the wireless device 305 is configured to transmit RF signals via the antenna 310 in a transmit mode. An example of the wireless device 305 in the transmit mode is shown in FIG. 5A. In the transmit mode, the control circuit 390 opens (i.e., turns off) the third switch 340, and closes (i.e., turns on) the first switch 330 and the second switch 335. In this mode, the second terminal 354 of the first inductor 350 is coupled to ground. The control circuit 390 also causes the switching circuit 380 to couple the PA 370 to the transformer 345.

In the transmit mode, the PA 370 receives an RF signal at the input 372 (e.g., from a mixer (not shown) or another circuit on the wireless device), amplifies the RF signal, and outputs the amplified RF signal at the outputs 374 and 376. In one example, the PA 370 may output the amplified RF signal as a differential current. The switching circuit 380 couples the amplified RF signal to the second inductor 360 of the transformer 345. The transformer 345 inductively (i.e., magnetically) couples the amplified RF signal from the second inductor 360 to the first inductor 350. In the example in FIG. 5A, the transformer 345 also converts the amplified RF signal from a differential signal at the second inductor 360 to a single-ended signal at the first inductor 350. However, it is to be appreciated that the present disclosure is not limited to this example. From the first inductor 350, the amplified RF signal is output to the antenna 310 for transmission through the first switch 330, which bypasses the LNA 320.

In the transmit mode, the LNA 320 may be turned off to prevent the RF signal from entering the LNA 320 (i.e., isolate the LNA 320 from the RF signal in the transmit path). For example, the LNA 320 may include one or more internal nodes (not shown in FIG. 5A) that are biased by one or more bias voltages when the LNA 230 is turned on in the receive mode. In this example, the one or more internal nodes may be grounded to turn off the LNA 320 in the transmit mode.

For implementations in which the wireless device 305 includes the transconductor 410, the transconductor 410 may be turned off in the transmit mode, as shown in FIG. 5B. Note that, in FIG. 4B, the label “(on)” indicates that the transconductor 410 is turned on in the receive mode, and, in FIG. 5B, the label “(off)” indicates that the transconductor 410 is turned off in the transmit mode. The transconductor 410 may be turned on and off by the control circuit 390.

In the example shown in FIG. 3, the switching circuit 380 includes a switch 382 coupled between the first terminal 362 of the second inductor 360 and the first output 374 of the PA 370, and a switch 384 coupled between the second terminal 364 of the inductor 360 and the second output 376 of the PA 370. In this example, the control circuit 390 opens (i.e., turns off) the switches 382 and 384 in the receive mode, as shown in FIGS. 4A and 4B. Also, in this example, the control circuit 390 closes (i.e., turns on) the switches 382 and 384 in the transmit mode, as shown in FIGS. 5A and 5B. In one example, each of the switches 382 and 384 may be implemented with a respective transistor (e.g., respective n-type field effect transistor (NFET) or a respective p-type field effect transistor (PFET)). It is to be appreciated that the switching circuit 380 is not limited to the exemplary implementation shown in FIG. 3.

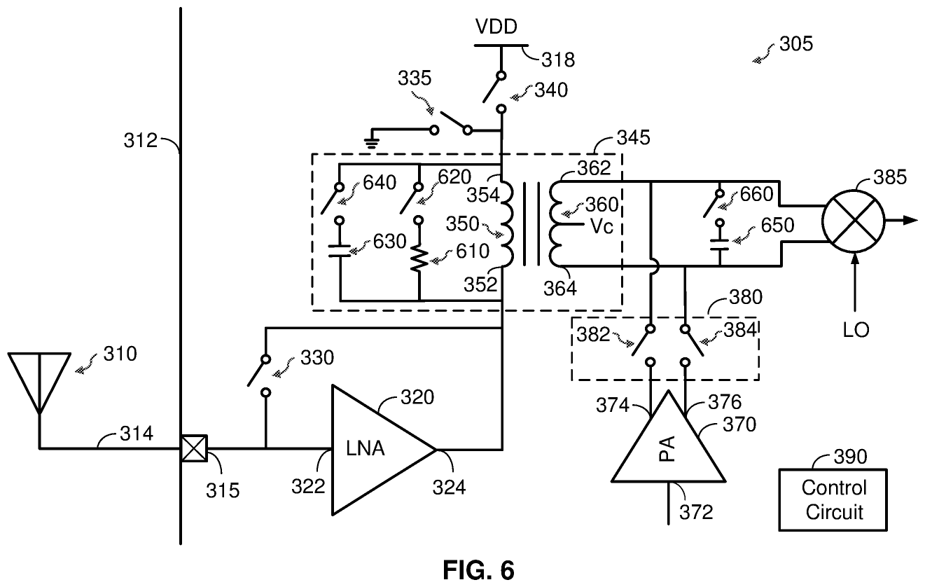

FIG. 6 shows an example in which the wireless device 305 further includes a resistor 610 and a fourth switch 620. The resistor 610 may be used to provide impedance matching in the transmit mode, as discussed further below. In this example, the resistor 610 and the fourth switch 620 are coupled in series between the first terminal 352 of the first inductor 350 and the second terminal 354 of the first inductor 350. Although not explicitly shown in FIG. 6, it is to be appreciated that the wireless device 305 may include the transconductor 410 in this example.

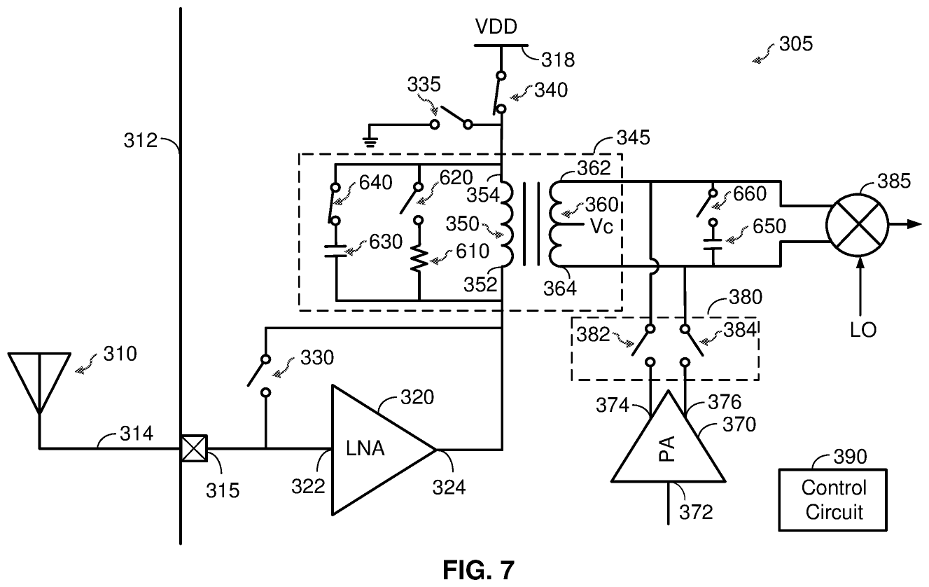

In the receive mode, the fourth switch 620 is open (i.e., turned off). An example of the wireless device 305 in the receive mode is shown in FIG. 7. As shown in FIG. 7, the control circuit 390 closes (i.e., turns on) the third switch 340, and opens (i.e., turns off) the first switch 330, the second switch 335, and the fourth switch 620.

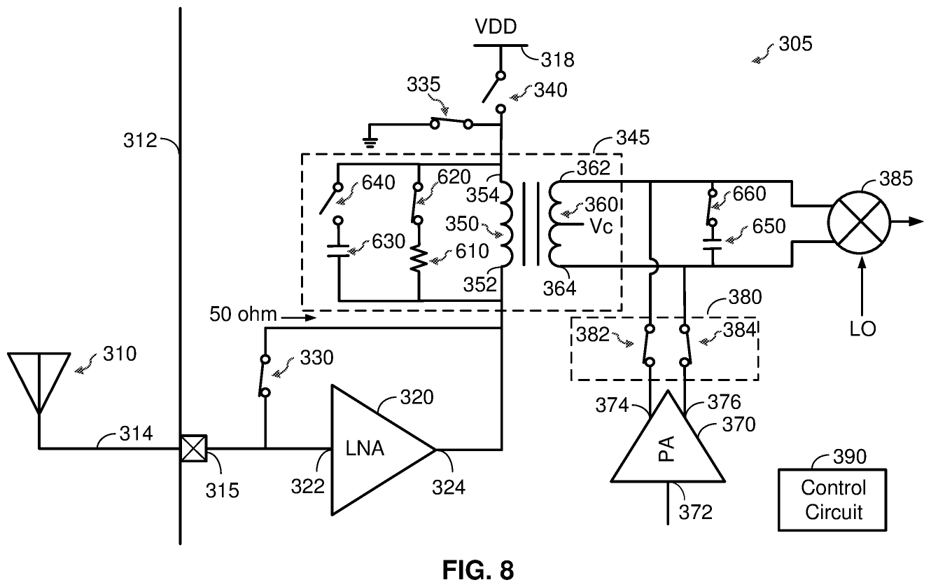

In the transmit mode, the fourth switch 620 is closed (i.e., turned on). An example of the wireless device 305 in the transmit mode in shown in FIG. 8. As shown in FIG. 8, the control circuit 390 opens (i.e., turns off) the third switch 340, and closes (i.e., turns on) the first switch 330, the second switch 335, and the fourth switch 620. As discussed above with reference to FIG. 5B, the wireless device 305 transmits an RF signal via the antenna 310 in the transmit mode.

In the transmit mode, the resistor 610 is coupled in parallel with the first inductor 350. In certain aspects, the resistance of the resistor 610 may be chosen to provide impedance matching with the transmission line 314 in the transmit mode. As shown in the example in FIG. 8, in the transmit mode, the resistor 610 may provide an impedance of 50 ohm looking into the transmit path for the case where the transmission line 314 has a characteristic impedance of 50 ohm. However, it is to be appreciated that the present disclosure is not limited to this example.

Although one switch 620 is shown coupled in series with the resistor 610 in the example in FIG. 6, it is to be appreciated that the wireless device 305 may include two switches coupled in series with the resistor 610 in which one of the switches is coupled to one end of the resistor 610 and the other one of the switches is coupled to the other end of the resistor 610. In this example, the switches may be open (i.e., turned off) in the receive mode and closed (i.e., turned on) in the transmit mode.

In certain aspects, the wireless device 305 may also include a first capacitor 630 and a fifth switch 640 coupled in series between the first terminal 352 of the first inductor 350 and the second terminal 354 of the first inductor 350. For example, the first capacitor 630 may be used with the first inductor 350 to provide an LC tank (also referred to as an LC load or circuit) coupled to the output 324 of the LNA 320. In this example, the first capacitor 630 may be implemented with a variable capacitor having a tunable (e.g., programmable) capacitance to tune the resonance frequency of the LC tank.

In the receive mode, the control circuit 390 may close (i.e., turn on) the fifth switch 640 to provide the LC tank at the output 324 of the LNA 320, as shown in FIG. 7. The resonance frequency of the LC tank may be tuned to provide high gain for the receiver in a desired frequency hand in the receive mode. In the transmit mode, the control circuit 390 may open (i.e., turn off) the fifth switch 640, as shown in FIG. 8.

Although one switch 640 is shown coupled in series with the first capacitor 630 in the example in FIG. 6, it is to be appreciated that the wireless device 305 may include two switches coupled in series with the first capacitor 630 in which one of the switches is coupled to one end of the first capacitor 630 and the other one of the switches is coupled to the other end of the first capacitor 630. In this example, the switches may be closed (i.e., turned on) in the receive mode and opened (i.e., turned off) in the transmit mode. However, it is to be appreciated that the present disclosure is not limited to this example.

In certain aspects, the wireless device 305 may also include a second capacitor 650 and a sixth switch 660 coupled in series between the first terminal 362 of the second inductor 360 and the second terminal 364 of the second inductor 360. For example, the second capacitor 650 may be used with the second inductor 360 to provide an LC tank coupled to the output of the PA 370. In this example, the second capacitor 650 may be implemented with a variable capacitor having a tunable (e.g., programmable) capacitance to tune the resonance frequency of the LC tank. For the example where the wireless device 305 includes the transconductor 410 (shown in FIGS. 4B and 5B), the transconductor 410 may be coupled between the second capacitor 650 and the mixer 385.

In the receive mode, the control circuit 390 may open (i.e., turn off) the sixth switch 660, as shown in FIG. 7. In the transmit mode, the control circuit 390 may close (i.e., turn on) the sixth switch 660 to provide the LC tank at the output of the PA 370 as shown in FIG. 8. The resonance frequency of the LC tank may be tuned to provide high gain for the transmitter in a desired frequency band in the transmit mode.

Although one switch 660 is shown coupled in series with the second capacitor 650 in the example in FIG. 6, it is to be appreciated that the wireless device 305 may include two switches coupled in series with the second capacitor 650 in which one of the switches is coupled to one end of the second capacitor 650 and the other one of the switches is coupled to the other end of the second capacitor 650. In this example, the switches may be closed (i.e., turned on) in the transmit mode and opened (i.e., turned off) in the receive mode. However, it is to be appreciated that the present disclosure is not limited to this example.

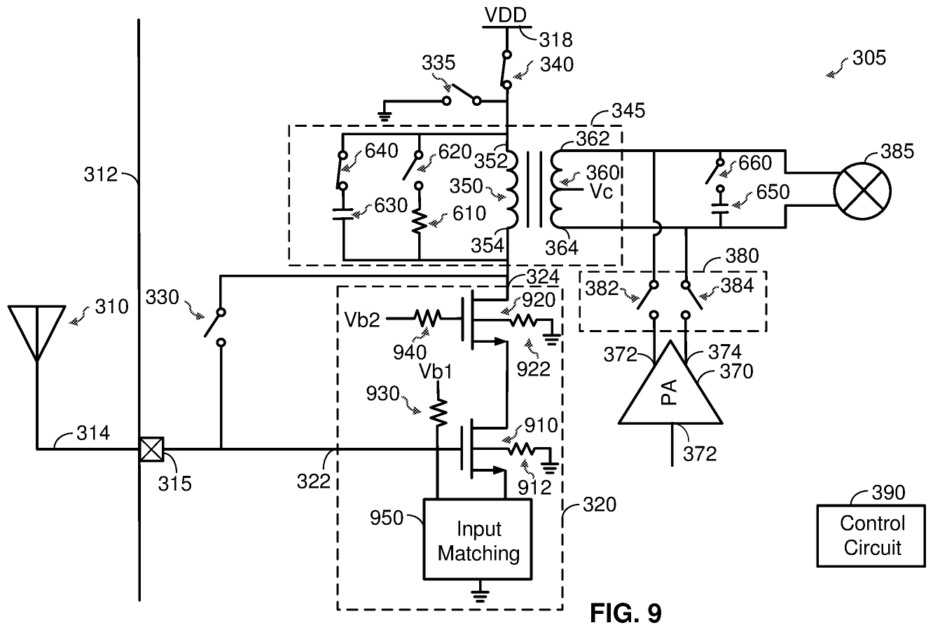

FIG. 9 shows an exemplary implementation of the LNA 320 according to certain aspects. In this example, the LNA 320 includes a first transistor 910, a second transistor 920, a first bias resistor 930, a second bias resistor 940, and an input matching circuit 950. In this example, the first transistor 910 is in a common-source configuration and the second transistor 920 is in a common-gate configuration. However, it is to be appreciated that the present disclosure is not limited to this example.

The gate of the first transistor 910 is coupled to the input 322 of the LNA 320. It is to be appreciated that, in some implementations, the gate of the first transistor 910 may be coupled to the input 322 via a coupling capacitor (not shown) between the gate of the first transistor 910 and the input 322. The first bias resistor 930 is coupled to the gate of the first transistor 910. The input matching circuit 950 is coupled to the gate and the source of the first transistor 910, and to ground. In certain aspects, the input matching circuit 950 is configured to provide impedance matching at the input 322 of the LNA 320. For example, the input matching circuit 950 may be configured to provide an impedance of 50 ohm at the input 322 to provide impedance matching for the case where the transmission line 314 has a characteristic impedance of 50 ohm. However, it is to be appreciated that the present disclosure is not limited to this example.

The source of the second transistor 920 is coupled to the drain of the first transistor 910, and the drain of the second transistor 920 is coupled to the output 324 of the LNA 320. The second bias resistor 940 is coupled to the gate of the second transistor 920. In the example in FIG. 9, each of the first transistor 910 and the second transistor 920 is implemented with a respective NFET. However, it is to be appreciated that the present disclosure is not limited to this example.

In the example shown in FIG. 6, the first transistor 910 has a bulk connection to ground through resistor 912, and the second transistor 920 has a bulk connection to ground through resistor 922. However, it is to be appreciated that the present disclosure is not limited to this example.

FIG. 9 shows an example of the LNA 320 in the receive mode. In this example, the gate of the first transistor 910 is biased by a first bias voltage (labeled “Vb1”) via the first bias resistor 930, and the gate of the second transistor 920 is biased by a second bias voltage (labeled “Vb2”) via the second bias resistor 940. In certain aspects, the second bias voltage may be approximately equal to the supply voltage VDD (e.g., 0.8V). However, it is to be appreciated that the second bias voltage is not limited to this example. The first bias voltage may be approximately equal to a voltage between the supply voltage VDD and ground.

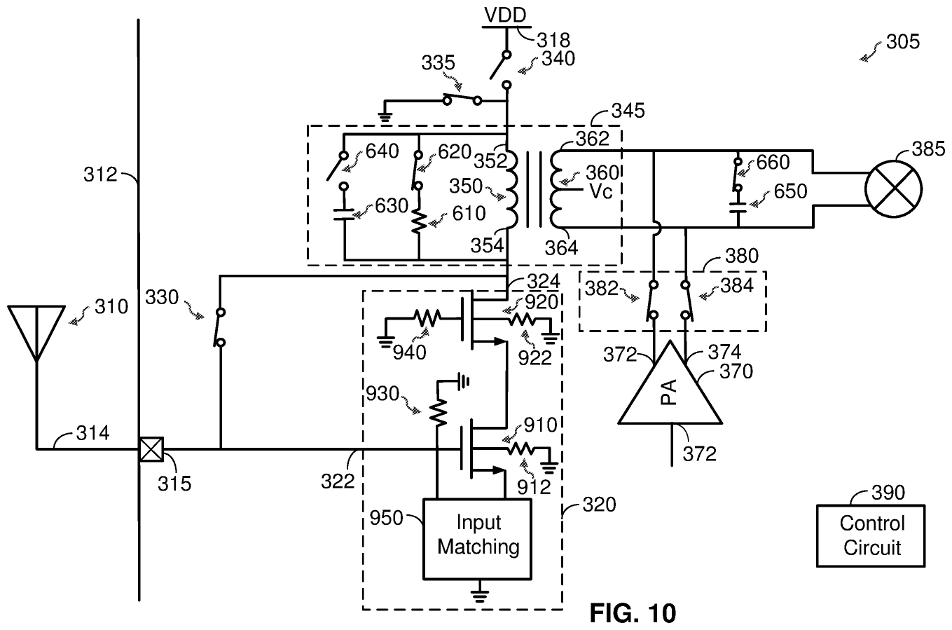

FIG. 10 shows an example of the LNA 320 in the transmit mode. In this example, the first bias resistor 930 and the second bias resistor 940 are grounded. In addition, the input matching circuit 950 is configured to have a high impedance in the transmit mode, which helps isolate the input 322 of the LNA 320 from the transmit path in the transmit mode.

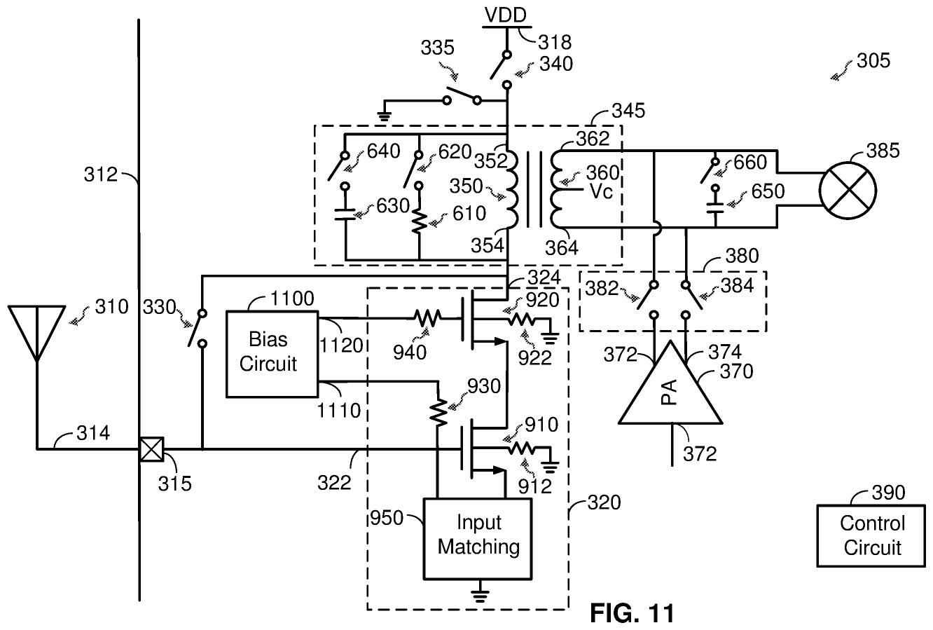

FIG. 11 shows an example in which the wireless device 305 includes a bias circuit 1100 according to certain aspects. The bias circuit 1100 is configured to bias the gate of the first transistor 910 and the gate of the second transistor 920. The bias circuit 1100 has a first terminal 1110 coupled to the gate of the first transistor 910 via the first bias resistor 930, and a second terminal 1120 coupled to the gate of the second transistor 920 via the second bias resistor 940.

In the receive mode, the bias circuit 1100 is configured to bias the gate of the first transistor 910 via the first terminal 1110 with the first bias voltage Vb1 shown in FIG. 9. The bias circuit 1100 may generate the first bias voltage Vb1, for example, using a voltage divider, a digital-to-analog converter, or another type of circuit. In the transmit mode, the bias circuit 1100 is configured to ground the first bias resistor 930 via the first terminal 1110. For example, the bias circuit 1100 may include a switch coupled between the first terminal 1110 and ground. In this example, the bias circuit 1100 may open the switch in the receive mode, and close the switch in the transmit mode to ground the first terminal 1110.

In the receive mode, the bias circuit 1100 is configured to bias the gate of the second transistor 920 via the second terminal 1120 at the second bias voltage Vb2 shown in FIG. 9. For the example in which the second bias voltage Vb2 is approximately equal to the supply voltage VDD, the bias circuit 1100 may couple the second terminal 1120 to the supply rail 318 in the receive mode. In the transmit mode, the bias circuit 1100 is configured to ground the second bias resistor 940 via the second terminal 1120. For example, the bias circuit 1100 may include a switch coupled between the second terminal 1120 and ground. In this example, the bias circuit 1100 may open the switch in the receive mode, and close the switch in the transmit mode to ground the second terminal 1120.

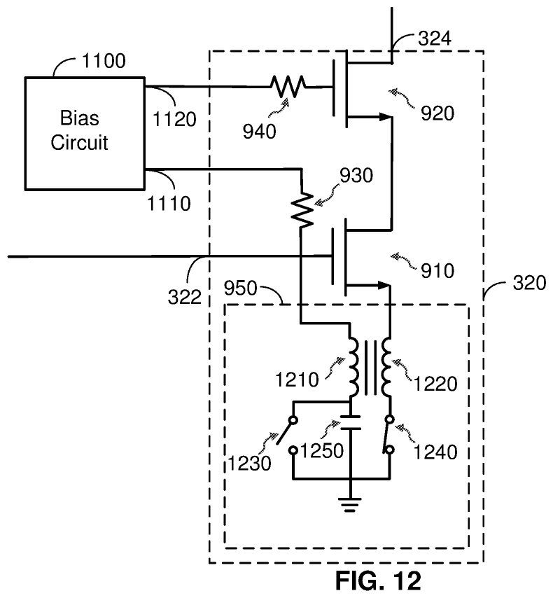

FIG. 12 shows an exemplary implementation of the input matching circuit 950 in the receive mode according to certain aspects. In this example, the input matching circuit 950 includes a source inductor 1220 and a switch 1240 coupled in series between the source of the first transistor 910 and ground. The source inductor 1220 may also be referred to as a source degeneration inductor. The input matching circuit 950 also includes a gate inductor 1210, a capacitor 1250, and a switch 1230 in parallel with the capacitor 1250. In this example, the gate inductor 1210 is coupled between the gate of the first transistor 910 and the capacitor 1250, and the capacitor 1250 is coupled between the gate inductor 1210 and ground. Also, the source inductor 1220 is inductively coupled with the gate inductor 1210 in this example. The switches 1240 and 1230 may be controlled by the control circuit 390.

As shown in FIG. 12, in the receive mode, the control circuit 390 closes (i.e., turns on) the switch 1240, which couples the source inductor 1220 between the source of the first transistor 910 and ground. In this mode, the source inductor 1220 provides the LNA 320 with source degeneration. Also, in the receive mode, the control circuit 390 opens (i.e., turns off) the switch 1230. As a result, the capacitor 1250 and the gate inductor 1210 form an L-C notch filter, which may be used for providing impedance matching at the input 322 of the LNA 320. For example, the inductance of the gate inductor 1210 and the capacitance of the capacitor 1250 may be chosen to provide an input impedance of 50 ohms for the case where the transmission line 314 has a characteristic impedance of 50 ohms. However, it is to be appreciated that the present disclosure is not limited to this example.

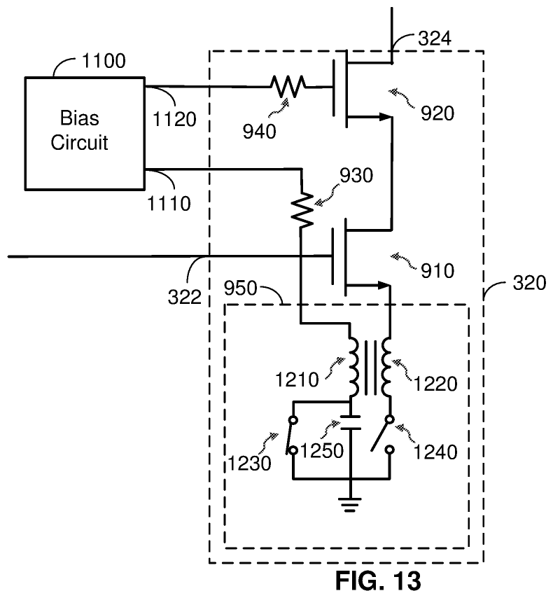

FIG. 13 shows the input matching circuit 950 in the transmit mode according to certain aspects. In this example, the control circuit 390 opens (i.e., turns off) the switch 1240, which decouples the source inductor 1220 from ground. This turns off the first transistor 910 and allows the source and gate of the first transistor 910 to track each other, which prevents the gate-to-source voltage of the first transistor 910 from becoming large in the transmit mode and potentially damaging the first transistor 910. Also, in the transmit mode, the control circuit 390 closes (i.e., turns on) the switch 1230, which grounds the gate inductor 1210.

It is to be appreciated that the input matching circuit 950 is not limited to the exemplary implementation shown in FIGS. 12 and 13. For example, in some implementations, the gate inductor 1210 may be coupled between the input 322 and the gate of the first transistor 910.

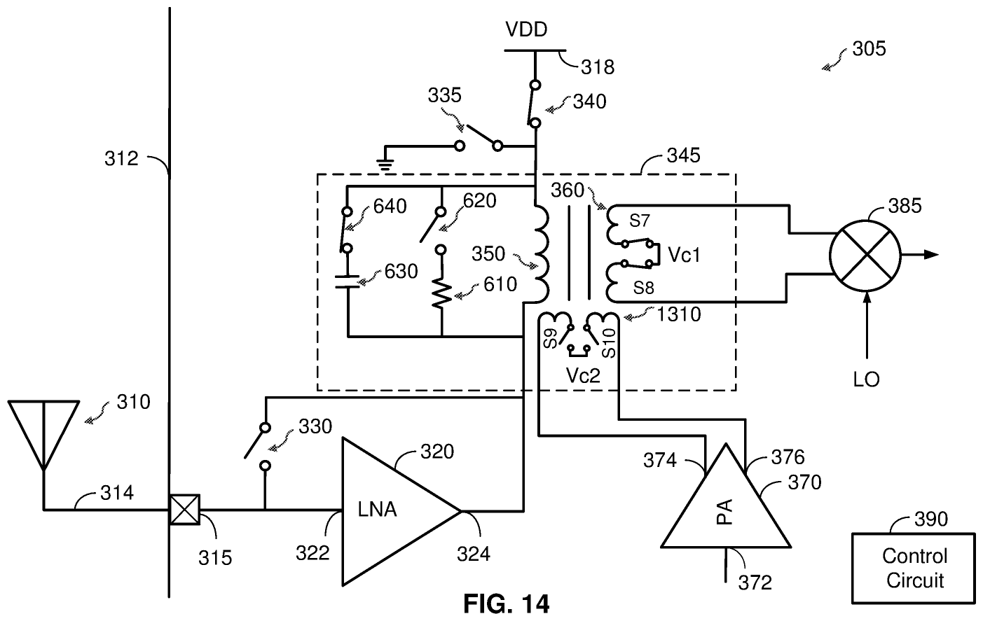

FIG. 14 shows another exemplary implementation of the transformer 345 according to certain aspects. In this example, the transformer 345 includes a third inductor 1310 inductively coupled with the first inductor 350. Thus, in this example, the transformer 345 includes three inductors and may be referred to as a three-winding transformer or another term.

In this example, the second inductor 360 has two portions with a seventh switch S7 and an eighth switch S8 coupled between the two portions. The center tap of the second inductor 360 (which is based by voltage Vc1) is between the seventh switch S7 and the eighth switch S8. The switches S7 and S8 are controlled by the control circuit 390. When the control circuit 390 closes (i.e., turns on) the switches S7 and S8, the portions of the second inductor 360 are coupled together. When the control circuit 390 opens (i.e., turns off) the switches S7 and S8, the portions of the second inductor 360 are decoupled and the second inductor 360 has a high impedance. As discussed further below, the second inductor 360 is used for the receive path in this example.

The third inductor 1310 is coupled between the first output 374 and the second output 76 of the PA 130. The third inductor has two portions with a ninth switch S9 and a tenth switch S10 coupled between the two portions. A center tap of the third inductor 1310 (which is based by voltage Vc2) is between the ninth switch S9 and the tenth switch S10. The switches S9 and S10 are controlled by the control circuit 390. When the control circuit 390 closes (i.e., turns on) the switches S9 and S10, the portions of the second inductor 360 are coupled together. When the control circuit 390 opens (i.e., turns off) the switches S9 and S10, the portions of the third inductor 1310 are decoupled and the third inductor 1310 has a high impedance. It is to be appreciated that the voltages Vc1 and Vc2 may be different or approximately equal.

FIG. 14 shows an example of the transformer 345 in the receive mode. In the receive mode, the control circuit 390 closes the seventh switch S7 and the eighth switch S8, and opens the ninth switch S9 and the tenth switch S10. In this mode, the RF signal from the LNA 320 is inductively coupled from the first inductor 350 to the second inductor 360. From the second inductor 360, the RF signal may be input to the mixer 385 or another circuit. Since the ninth switch S9 and the tenth switch S10 are open in this mode, the third inductor 1310 has a high impedance, which helps minimize coupling of the RF signal from the LNA 320 to the third inductor 1310 in the receive mode.

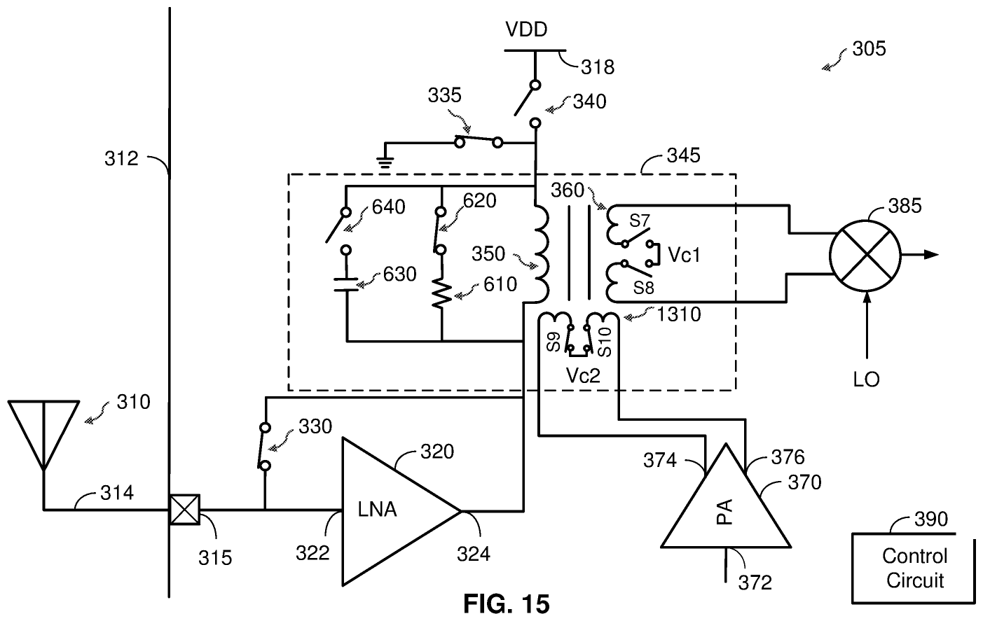

FIG. 15 shows an example of the transformer 345 in the transmit mode. In the transmit mode, the control circuit 390 opens the seventh switch S7 and the eighth switch S8, and closes the ninth switch S9 and the tenth switch S10. In this mode, the RF signal from the PA 370 is inductively coupled from the third inductor 1310 to the first inductor 350. From the first inductor 350, the RF signal may be output to the antenna 310 for transmission. Since the seventh switch S7 and the eighth switch S8 are open in this mode, the second inductor 360 has a high impedance, which helps minimize coupling of the RF signal from the PA 370 to the second inductor 360 in the transmit mode.

It is to be appreciated that the transformer 345 is not limited to the seventh switch S7 and the eighth switch S8 shown in FIGS. 14 and 15. In general, the transformer 345 may include one or more first inductor switches (e.g., S7 and S8) coupled in series with the second inductor 360 in which the control circuit 390 closes the one or more first inductor switches in the receive mode and opens the one or more first inductor switches in the transmit mode. Also, it is to be appreciated that the transformer 345 is not limited to the ninth switch S9 and the tenth switch S10 shown in FIGS. 14 and 15. In general, the transformer 345 may include one or more second inductor switches (e.g., S9 and S10) coupled in series with the third inductor 1310 in which the control circuit 390 opens the one or more second inductor switches in the receive mode and closes the one or more second inductor switches in the transmit mode.

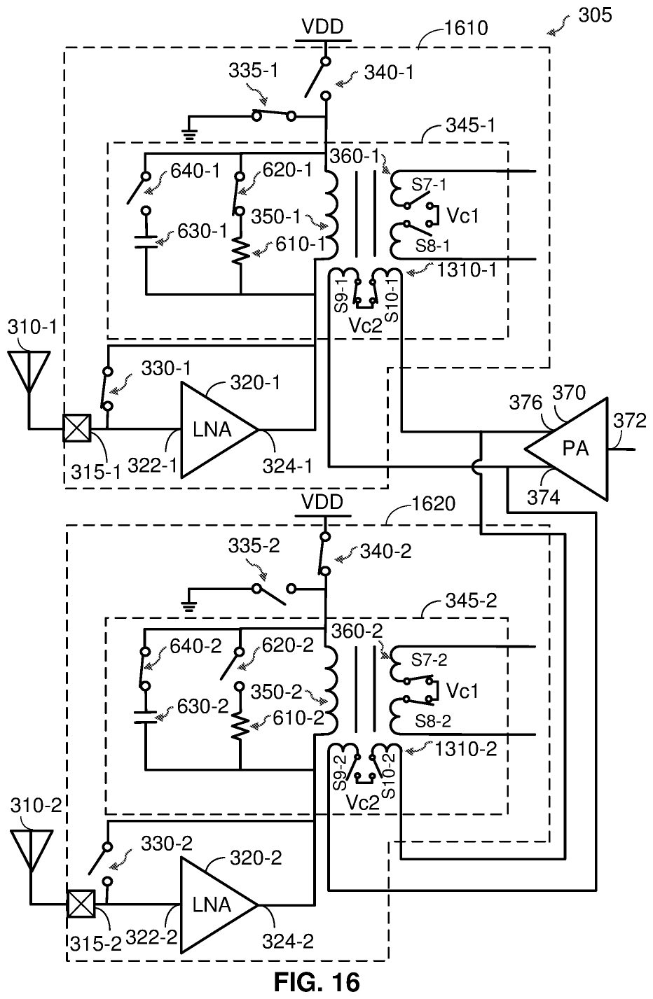

In certain aspects, the PA 370 may be shared by two or more antennas. For example, the PA 370 may be switched between two or more antennas. In this regard, FIG. 16 shows an example in which the PA 370 can be switched between a first antenna 310-1 and a second antenna 310-2. In this example, the wireless device 305 includes a first circuit 1610 coupled to the first antenna 310-1 and a second circuit 1620 coupled to the second antenna 310-2. Each of the circuits 1610 and 1620 includes a separate instance (i.e., copy) of the switches, the transformer 345, and the LNA 320 shown in FIGS. 14 and 15. Thus, the descriptions of these elements given above apply to each of the circuits 1610 and 1620. In FIG. 16, the elements of the first circuit 1610 include the suffix one and the elements of the second circuit 1620 include the suffix two in order to distinguish the elements of the first circuit 1610 from the elements of the second circuit 1620.

In the example in FIG. 16, the third inductor 1310-1 in the first circuit 1610 is coupled between the first output 374 and the second output 376 of the PA 370. The third inductor 1310-2 in the second circuit 1620 is also coupled between the first output 374 and the second output 376 of the PA 370. This allows the PA 370 to transmit via the first antenna 310-1 and/or the second antenna 310-2, as discussed further below.

FIG. 16 shows an example in which the PA 370 transmits via the first antenna 310-1 (e.g., in a first mode). In this example, the control circuit 390 (not shown in FIG. 16) closes the ninth S9-1 and tenth switch S10-1 in the first circuit 1610, and opens the ninth S9-2 and tenth switch S10-2 in the second circuit 1620. In this example, the transformer 345-1 in the first circuit 1610 couples the RF signal from the PA 370 to the first antenna 310-1 for transmission. The control circuit 390 may also open the seventh switch S7-1 and the eighth switch S8-1 in the first circuit 1610. In some implementations, the wireless device 305 may receive an RF signal via the second antenna 310-2 while transmitting an RF signal via the first antenna 310-1. In this case, the control circuit 390 may close the seventh switch S7-2 and the eighth switch S8-2 in the second circuit 1620 to receive an RF signal via the second antenna 310-2 using the second circuit 1620. However, it is to be appreciated that the present disclosure is not limited to this example.

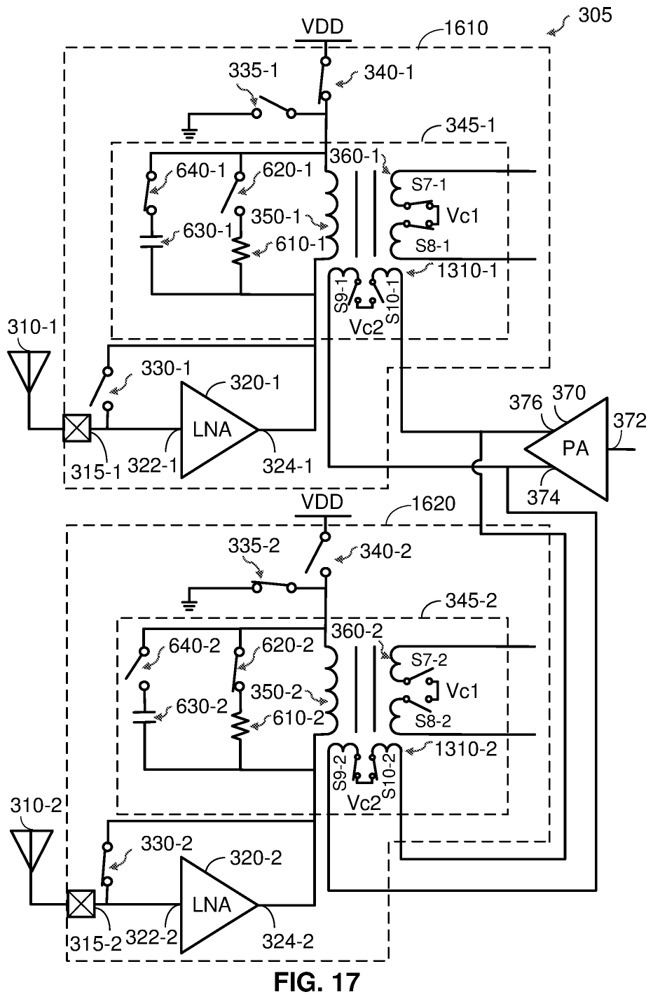

FIG. 17 shows an example in which the PA 370 transmits via the second antenna 310-2 (e.g., in a second mode). In this example, the control circuit 390 (not shown in FIG. 17) closes the ninth S9-2 and tenth switch S10-2 in the second circuit 1620, and opens the ninth S9-1 and tenth switch S10-1 in the first circuit 1610. In this example, the transformer 345-2 in the second circuit 1620 couples the RF signal from the PA 370 to the second antenna 310-2 for transmission. The control circuit 390 may also open the seventh switch S7-2 and the eighth switch S8-2 in the second circuit 1620. In some implementations, the wireless device 305 may receive an RF signal via the first antenna 310-1 while transmitting an RF signal via the second antenna 310-2. In this case, the control circuit 390 may close the seventh switch S7-1 and the eighth switch S8-1 in the first circuit 1610 to receive an RF signal via the first antenna 310-1 using the first circuit 1610. However, it is to be appreciated that the present disclosure is not limited to this example.

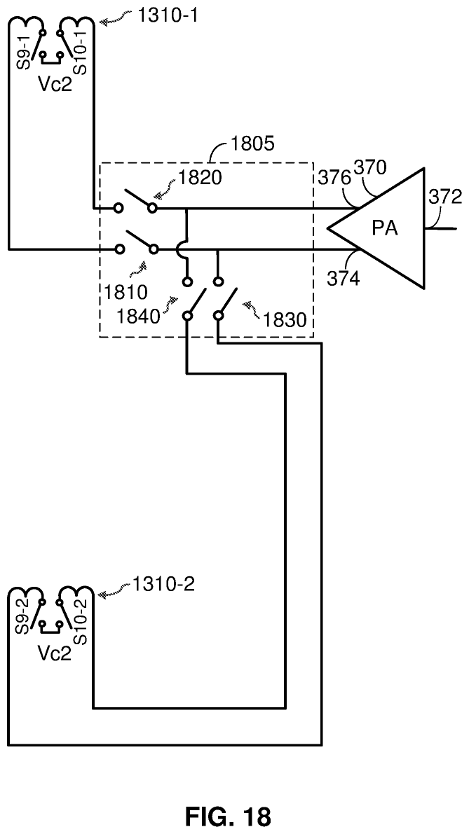

FIG. 18 shows an example in which the wireless device 305 includes a switching circuit 1805 coupled to the transformer 345-1 in the first circuit 1610, the transformer 345-2 in the second circuit 1620, and the output of the PA 370. The switching circuit 1805 is configured to switch the output of the PA 370 between the transformer 345-1 in the first circuit 1610, and the transformer 345-2 in the second circuit 1620, as discussed further below. The switching of the switching circuit 1805 may be controlled by the control circuit 390 (not shown in FIG. 18). Note that only a portion of each of the first circuit 1610 and the second circuit 1620 is shown in FIG. 18 for ease of illustration.

To transmit via the first antenna 310-1, the control circuit 390 causes the switching circuit 1805 to couple the output of the PA 370 to the transformer 345-1 in the first circuit 1610 and decouple the output of the PA 370 from the transformer 345-2 in the second circuit 1620. To transmit via the second antenna 310-2, the control circuit 390 causes the switching circuit 1805 to couple the output of the PA 370 to the transformer 345-2 in the second circuit 1620 and decouple the output of the PA 370 from the transformer 345-1 in the first circuit 1610.

In the example shown in FIG. 18, the switching circuit 1805 includes a first switch 1810 coupled between the first output 374 of the PA 370 and a first terminal of the third inductor 1310-1, and a second switch 1820 coupled between the second output 376 of the PA 370 and a second terminal of the third inductor 1310-1. The switching circuit 1805 also includes a third switch 1830 coupled between the first output 374 of the PA 370 and a first terminal of the third inductor 1310-2, and a fourth switch 1840 coupled between the second output 376 of the PA 370 and a second terminal of the third inductor 1310-2. Each of the switches 1810, 1820, 1830, and 1840 may be implemented with a respective transistor or another type of switch.

In this example, to transmit on the first antenna 310-1 (e.g., in the first mode), the control circuit 390 closes the first switch 1810 and the second switch 1820 to couple the PA 370 to the transformer 345-1 in the first circuit 1610, and opens the third switch 1830 and the fourth switch 1840 to decouple the PA 370 from the transformer 345-2 in the second circuit 1620. To transmit on the second antenna 310-2 (e.g., in the second mode), the control circuit 390 opens the first switch 1810 and the second switch 1820 to decouple the PA 370 from the transformer 345-1 in the first circuit 1610, and closes the third switch 1830 and the fourth switch 1840 to couple the PA 370 to the transformer 345-2 in the second circuit 1620.

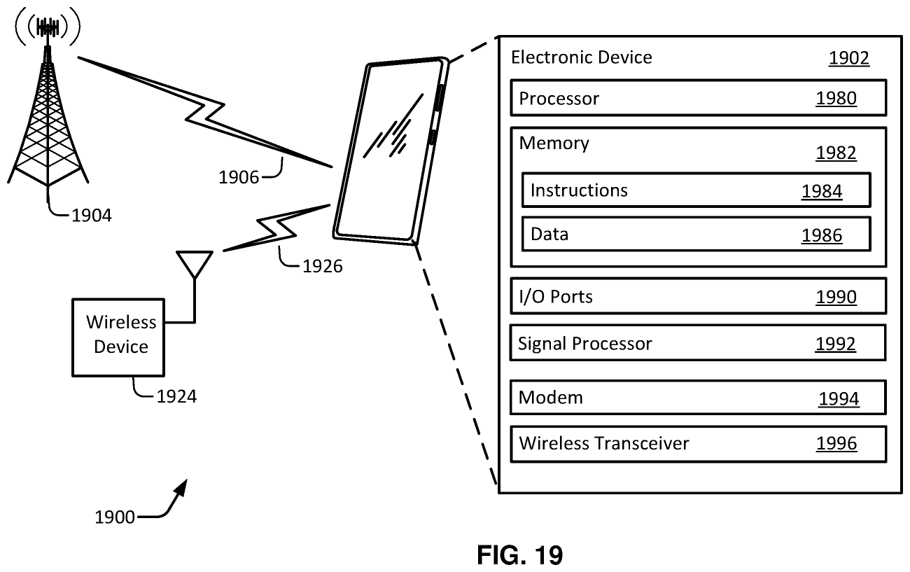

FIG. 19 is a diagram of an environment 1900 that includes an electronic device 1902, a base station 1904, and a wireless device 1924. The electronic device 1902 may correspond to the wireless device 305. The electronic device 1902 includes a wireless transceiver 1996, which may include the LNA 320, the transformer 345, the PA 370, the switches 330, 335, and 340, the transconductor 410, the mixer 385, the switching circuit 380, the first circuit 1610, and/or the second circuit 1620.

In the environment 1900, the electronic device 1902 communicates with the base station 1904 via a wireless link 1906 and/or communicates with the wireless device 1924 via a wireless link 1926. As shown, the electronic device 1902 is depicted as a smart phone. However, the electronic device 1902 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 1904 may communicate with the electronic device 1902 via the wireless link 1906, which may be implemented as any suitable type of wireless link. Although depicted as a base station tower of a cellular radio network, the base station 1904 may represent or be implemented as another device, such as a satellite, terrestrial broadcast tower, access point, peer to peer device, mesh network node, fiber optic line, another electronic device generally as described above, and so forth. Hence, the electronic device 1902 may communicate with the base station 1904 or another device via a wired connection, a wireless connection, or a combination thereof. The wireless link 1906 can include a downlink of data or control information communicated from the base station 1904 to the electronic device 1902 and an uplink of other data or control information communicated from the electronic device 1902 to the base station 1904. The wireless link 1906 may be implemented using any suitable communication protocol or standard, such as 3rd Generation Partnership Project Long-Term Evolution (3GPP LTE, 3GPP NR 5G), IEEE 1902.19, IEEE 1902.19, Bluetooth™, and so forth.

The wireless device 1924 may communicate with the electronic device 1902 via the wireless link 1926, which may be any suitable type of wireless link. The wireless device 1924 may be implemented as a cellular or mobile phone, gaming device, navigation device, media device, laptop computer, desktop computer, tablet computer, server computer, a wireless key, network-attached storage (NAS) device, smart appliance, vehicle-based communication system, Internet of Things (IoT) device, sensor or security device, asset tracker, and so forth. In certain aspects, the electronic device 1902 may communicate with the wireless device 1924 using one or more short-range wireless communication technologies. For example, the electronic device 1902 may communicate with the wireless device 1924 using an ultra-wideband (UWB) technology. UWB connectivity is a short-range, wireless communication protocol that operates with a very high frequency as compared to other short-range wireless communication technologies (e.g., Bluetooth, WLAN, Zigbee, or the like) and uses a relatively wide frequency band (e.g., 500 MHz or greater) as compared to other short-range wireless communication technologies, which makes UWB useable for high-resolution positioning and localization purposes. However, it is to be appreciated that the electronic device 1902 is not limited to UWB and may communicate with the wireless device 1924 using other wireless communication technologies.

The electronic device 1902 includes a processor 1980 and a memory 1982. The memory 1982 may be or form a portion of a computer readable storage medium. The processor 1980 may include any type of processor, such as an application processor or a multi-core processor, that is configured to execute processor-executable instructions (e.g., code) stored in the memory 1982. The memory 1982 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 1982 is implemented to store instructions 1984, data 1986, and other information of the electronic device 1902.

The electronic device 1902 may also include input/output (I/O) ports 1990. The/O ports 1990 enable data exchanges or interaction with other devices, networks, or users or between components of the device.

The electronic device 1902 may further include a signal processor (SP) 1992 (e.g., such as a digital signal processor (DSP)). The signal processor 1992 may function similar to the processor 1980 and may be capable of executing instructions and/or processing information in conjunction with the memory 1982.

For communication purposes, the electronic device 1902 also includes a modem 1994, the wireless transceiver 1996, and one or more antennas (e.g., the antenna 310, the first antenna 310-1, and/or the second antenna 310-2). The modem 1994 may be coupled to the mixer 385 to process the frequency down-converted signal from the mixer 385. The wireless transceiver 1996 provides connectivity to respective networks and other electronic devices connected therewith using RF wireless signals. The wireless transceiver 1996 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN). The wireless transceiver 1996 may also facilitate communication with the wireless device 1924 using UWB and/or other short-range wireless communication technologies.

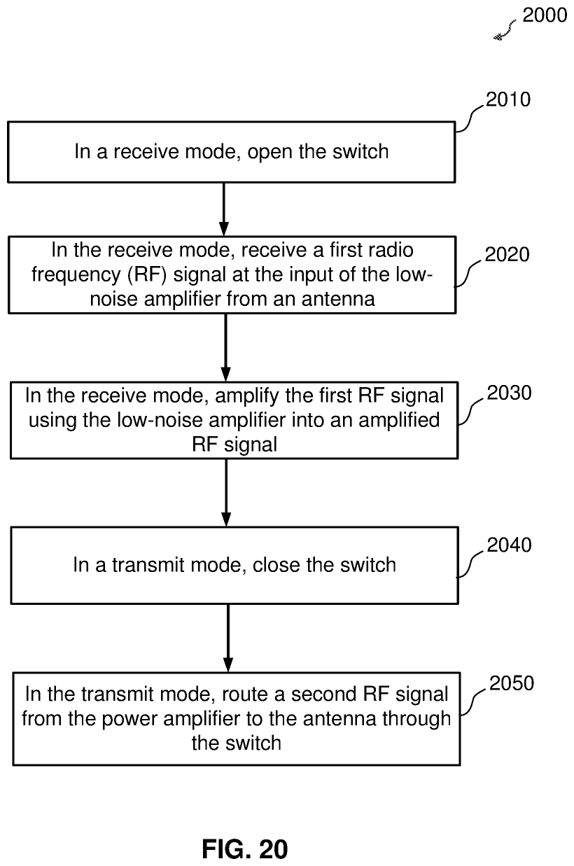

FIG. 20 illustrates an exemplary method 2000 for operating a wireless device according to certain aspects. The wireless device (e.g., wireless device 305) includes a low-noise amplifier (e.g., low-noise amplifier 320) having an input (e.g., input 322) and an output (e.g., output 324), a switch (e.g., switch 330) coupled between the input of the low-noise amplifier and the output of the low-noise amplifier, and a power amplifier (e.g., power amplifier 370).

At block 2010, in a receive mode, the switch is opened. For example, the switch may be opened by the control circuit 390.

At block 2020, a first radio frequency (RF) signal is received at the input of the low-noise amplifier from an antenna. For example, the antenna may correspond to antenna 310.

At block 2030, the first RF signal is amplified using the low-noise amplifier into an amplified RF signal; and

At block 2040, in a transmit mode, the switch is closed. For example, the switch may be closed by the control circuit 390.

At block 2050, a second RF signal is routed from the power amplifier to the antenna through the switch. For example, the second RF signal may be routed by the switching circuit 380 and the transformer 345.

In certain aspects, the method 2000 may also include, in the receive mode, inductively coupling the amplified RF signal to a mixer using a transformer. For example, the transformer may correspond to the transformer 345 and the mixer may correspond to the mixer 385.

In certain aspects, routing the second RF signal to the antenna through the switch may include inductively coupling the second RF signal from the power amplifier to the switch using the transformer. The transformer may correspond to the transformer 345.

In certain aspects, the transformer (e.g., transformer 345) includes an inductor (e.g., the first inductor 350), and the output of the low-noise amplifier is coupled to a first terminal of the inductor. In this example, the method 2000 may further include, in the receive mode, coupling a second terminal of the inductor to a supply rail, and, in the transmit mode, coupling the second terminal of the inductor to a ground. For example, the second terminal of the inductor may be coupled to the supply rail by closing the third switch 340, and the second terminal of the inductor may be coupled to the ground by closing the second switch 335.

The method 2000 may also include, in the transmit mode, coupling a resistor between the first terminal and the second terminal of the inductor, and in the receive mode, decoupling the resistor from at least one of the first terminal and the second terminal of the inductor. For example, the resistor may correspond to resistor 610, and the resistor 610 may be coupled between the first terminal and the second terminal of the inductor by closing the fourth switch 620, and decoupled from at least one of the first terminal and the second terminal of the inductor by opening the fourth switch 620.

The method 2000 may also include, in the receive mode, coupling a capacitor between the first terminal and the second terminal of the inductor, and in the transmit mode, decoupling the capacitor from at least one of the first terminal and the second terminal of the inductor. For example, the capacitor may correspond to capacitor 630, and the capacitor 630 may be coupled between the first terminal and the second terminal of the inductor by closing the fifth switch 640, and decoupled from at least one of the first terminal and the second terminal of the inductor by opening the fifth switch 640.

The control circuit 390 may be implemented with a general-purpose processor, a digital signal processor (DSP), an application specific integrated circuit (ASIC), a field programmable gate array (FPGA) or other programmable logic device, discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

Implementation examples are described in the following numbered clauses:

1. An apparatus, comprising:
a low-noise amplifier having an input and an output;
a first switch coupled between the input of the low-noise amplifier and the output of the low-noise amplifier;
a transformer including a first inductor and a second inductor, wherein the first inductor is coupled to the output of the low-noise amplifier;
a power amplifier having an input and an output; and
a switching circuit coupled between the output of the power amplifier and the second inductor.

2. The apparatus of clause 1, further comprising a control circuit configured to:
in a receive mode, open the first switch and cause the switching circuit to decouple the output of the power amplifier from the second inductor; and
in a transmit mode, close the first switch and cause the switching circuit to couple the output of the power amplifier to the second inductor.

3. The apparatus of clause 2, wherein:
the output of the power amplifier comprises a first output and a second output;
the switching circuit comprises a second switch coupled between the first output and a first terminal of the second inductor, and a third switch coupled between the second output and a second terminal of the second inductor; and
the control circuit is configured to:
in the receive mode, open the second switch and open the third switch; and
in the transmit mode, close the second switch and close the third switch.

4. The apparatus of clause 1 or 2, further comprising:
a second switch coupled between the first inductor and a ground; and
a third switch coupled between the first inductor and a supply rail.

5. The apparatus of clause 4, wherein:
the output of the low-noise amplifier is coupled to a first terminal of the first inductor;
the second switch is coupled between a second terminal of the first inductor and the ground; and
the third switch coupled between the second terminal of the first inductor and the supply rail.

6. The apparatus of clause 4 or 5, further comprising a control circuit configured to:
in a receive mode, open the first switch, open the second switch, and close the third switch; and
in a transmit mode, close the first switch, close the second switch, and open the third switch.

7. The apparatus of clause 6, wherein the control circuit is further configured to:
in the receive mode, cause the switching circuit to decouple the output of the power amplifier from the second inductor; and
in a transmit mode, cause the switching circuit to couple the output of the power amplifier to the second inductor.

8. The apparatus of any one of clauses 1 to 7, wherein the low-noise amplifier comprises:
a first transistor, wherein a gate of the first transistor is coupled to the input of the low-noise amplifier;
a source inductor coupled to a source of the first transistor; and
a second transistor, wherein a drain of the second transistor is coupled to the output of the low-noise amplifier, and a source of the second transistor is coupled to a drain of the first transistor.

9. The apparatus of clause 8, further comprising a second switch, wherein the source inductor and the second switch are coupled in series between the source of the first transistor and a ground.

10. The apparatus of clause 9, further comprising a control circuit configured to:
in a receive mode, open the first switch, close the second switch, and cause the switching circuit to decouple the output of the power amplifier from the second inductor; and
in a transmit mode, close the first switch, open the second switch, and cause the switching circuit to couple the output of the power amplifier to the second inductor.

11. The apparatus of any one of clauses 8 to 10, further comprising a bias circuit coupled to the gate of the first transistor and a gate of the second transistor, wherein the bias circuit is configured to:
in a receive mode, bias the gate of the first transistor at a first voltage, and bias the gate of the second transistor at a second voltage; and
in a transmit mode, couple the gate of the first transistor to a ground via a first resistor, and couple the gate of the second transistor to the ground via a second resistor.

12. The apparatus of any one of clauses 1 to 11, further comprising a mixer coupled to the second inductor.

13. The apparatus of any one of clauses 1 to 12, further comprising:
a resistor; and
a second switch, wherein the second switch and the resistor are coupled in series between a first terminal of the first inductor and a second terminal of the first inductor.

14. The apparatus of clause 13, further comprising a control circuit configured to:
in a receive mode, open the first switch, open the second switch, and cause the switching circuit to decouple the output of the power amplifier from the second inductor; and
in a transmit mode, close the first switch, close the second switch, and cause the switching circuit to couple the output of the power amplifier to the second inductor.

15. The apparatus of any one of clauses 1 to 12, further comprising:
a capacitor; and
a second switch, wherein the second switch and the capacitor are coupled in series between a first terminal of the first inductor and a second terminal of the first inductor.

16. The apparatus of clause 15, further comprising a control circuit configured to:
in a receive mode, open the first switch, close the second switch, and cause the switching circuit to decouple the output of the power amplifier from the second inductor; and
in a transmit mode, close the first switch, open the second switch, and cause the switching circuit to couple the output of the power amplifier to the second inductor.

17. The apparatus of clause 15 or 16, further comprising:
a resistor; and
a third switch, wherein the third switch and the resistor are coupled in series between the first terminal of the first inductor and the second terminal of the first inductor.

18. The apparatus of any one of clauses 1 to 17, further comprising:
a second low-noise amplifier having an input and an output;
a second switch coupled between the input of the second low-noise amplifier and the output of the second low-noise amplifier; and
a second transformer including a third inductor and a fourth inductor, wherein the third inductor is coupled to the output of the second low-noise amplifier;
wherein the switching circuit is coupled between the output of the power amplifier and the fourth inductor.

19. The apparatus of clause 18, further comprising a control circuit configured to:
in a first mode, cause the switching circuit to couple the output of the power amplifier to the second inductor and decouple the output of the power amplifier from the fourth inductor; and
in a second mode, cause the switching circuit to decouple the output of the power amplifier from the second inductor and couple the output of the power amplifier to the fourth inductor.

20. The apparatus of clause 19, wherein the control circuit is configured to:
in the first mode, close the first switch and open the second switch; and
in the second mode, open the first switch and close the second switch.

21. An apparatus, comprising:
a low-noise amplifier having an input and an output;
a first switch coupled between the input of the low-noise amplifier and the output of the low-noise amplifier;
a transformer including a first inductor, a second inductor, a third inductor, one or more first inductor switches coupled in series with the second inductor, and one or more second inductor switches coupled is series with the third inductor, wherein the first inductor is coupled to the output of the low-noise amplifier; and
a power amplifier having an input and an output, wherein the output of the power amplifier is coupled to the third inductor.

22. The apparatus of clause 21, further comprising a control circuit configured to:
in a receive mode, open the first switch, close the one or more first inductor switches, and open the one or more second inductor switches; and
in a transmit mode, close the first switch, open the one or more first inductor switches, and close the one or more second inductor switches.

23. The apparatus of clause 21 or 22, wherein:
the output of the power amplifier comprises a first output and a second output; and
the third inductor and the one or more second inductor switches are coupled in series between the first output and the second output of the power amplifier.

24. The apparatus of any one of clauses 21 to 23, further comprising:
a second switch coupled between the first inductor and a ground; and
a third switch coupled between the first inductor and a supply rail.

25. The apparatus of clause 24, wherein:
the output of the low-noise amplifier is coupled to a first terminal of the first inductor;
the second switch is coupled between a second terminal of the first inductor and the ground; and
the third switch coupled between the second terminal of the first inductor and the supply rail.

26. The apparatus of clause 24 or 25, further comprising a control circuit configured to:
in a receive mode, open the first switch, open the second switch, close the third switch, close the one or more first inductor switches, and open the one or more second inductor switches; and
in a transmit mode, close the first switch, close the second switch, open the third switch, open the one or more first inductor switches, and close the one or more second inductor switches.

27. The apparatus of any one of clauses 21 to 26, wherein the low-noise amplifier comprises:
a first transistor, wherein a gate of the first transistor is coupled to the input of the low-noise amplifier;
a source inductor coupled to a source of the first transistor; and
a second transistor, wherein a drain of the second transistor is coupled to the output of the low-noise amplifier, and a source of the second transistor is coupled to a drain of the first transistor.

28. The apparatus of clause 27, further comprising a second switch, wherein the source inductor and the second switch are coupled in series between the source of the first transistor and a ground.

29. The apparatus of clause 28, further comprising a control circuit configured to:
in a receive mode, open the first switch, close the second switch, close the one or more first inductor switches, and open the one or more second inductor switches; and
in a transmit mode, close the first switch, open the second switch, open the one or more first inductor switches, and close the one or more second inductor switches.

30. The apparatus of any one of clauses 21 to 29, further comprising a mixer coupled to the second inductor.

31. A method for operating a wireless device, wherein the wireless device includes a low-noise amplifier having an input and an output, a switch coupled between the input of the low-noise amplifier and the output of the low-noise amplifier, and a power amplifier, the method comprising:
in a receive mode.
   opening the switch;
   receiving a first radio frequency (RF) signal at the input of the low-noise amplifier from an antenna; and
   amplifying the first RF signal using the low-noise amplifier into an amplified RF signal; and
in a transmit mode,
   closing the switch; and
   routing a second RF signal from the power amplifier to the antenna through the switch.

32. The method of clause 31, further comprising, in the receive mode, inductively coupling the amplified RF signal to a mixer using a transformer.

33. The method of clause 31 or 32, wherein routing the second RF signal to the antenna through the switch comprises inductively coupling the second RF signal from the power amplifier to the switch using a transformer.

34. The method of clause 33, wherein the transformer includes an inductor, and the output of the low-noise amplifier is coupled to a first terminal of the inductor, the method comprising:
in the receive mode, coupling a second terminal of the inductor to a supply rail; and
in the transmit mode, coupling the second terminal of the inductor to a ground.

35. The method of clause 33 or 34, further comprising:
in the transmit mode, coupling a resistor between a first terminal and a second terminal of the inductor; and
in the receive mode, decoupling the resistor from at least one of the first terminal and the second terminal of the inductor.

36. The method of any one of clauses 33 to 35, further comprising:
in the receive mode, coupling a capacitor between a first terminal and a second terminal of the inductor; and
in the transmit mode, decoupling the capacitor from at least one of the first terminal and the second terminal of the inductor.

37. An apparatus, comprising:
a low-noise amplifier having an input and an output;
a switch coupled between the input of the low-noise amplifier and the output of the low-noise amplifier;
a power amplifier;
means for opening the switch in a receive mode;
means for inputting a first radio frequency (RF) signal from an antenna to the input of the low-noise amplifier in the receive mode;
means for closing the switch in a transmit mode; and
means for routing a second RF signal from the power amplifier to the antenna through the switch in the transmit mode.

It is to be appreciated that the present disclosure is not limited to the exemplary terminology used above to describe aspects of the present disclosure. For example, an inductor of a transformer may also be referred to as a winding or another term. Also, it is to be appreciated that an inductor may be referred to as a coil even in cases where the inductor is not physically implemented with a coil.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. An AC ground may be provided by a DC voltage.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus, comprising:
a low-noise amplifier having an input and an output;
a first switch coupled between the input of the low-noise amplifier and the output of the low-noise amplifier;
a transformer including a first inductor and a second inductor, wherein the first inductor is coupled to the output of the low-noise amplifier;
a power amplifier having an input and an output; and
a switching circuit coupled between the output of the power amplifier and the second inductor.

2. The apparatus of claim 1, further comprising a control circuit configured to:
in a receive mode, open the first switch and cause the switching circuit to decouple the output of the power amplifier from the second inductor; and
in a transmit mode, close the first switch and cause the switching circuit to couple the output of the power amplifier to the second inductor.

3. The apparatus of claim 2, wherein:
the output of the power amplifier comprises a first output and a second output;
the switching circuit comprises a second switch coupled between the first output and a first terminal of the second inductor, and a third switch coupled between the second output and a second terminal of the second inductor; and
the control circuit is configured to:
in the receive mode, open the second switch and open the third switch; and
in the transmit mode, close the second switch and close the third switch.

4. The apparatus of claim 1, further comprising:
a second switch coupled between the first inductor and a ground; and
a third switch coupled between the first inductor and a supply rail.

5. The apparatus of claim 4, wherein:
the output of the low-noise amplifier is coupled to a first terminal of the first inductor;
the second switch is coupled between a second terminal of the first inductor and the ground; and
the third switch coupled between the second terminal of the first inductor and the supply rail.

6. The apparatus of claim 4, further comprising a control circuit configured to:
in a receive mode, open the first switch, open the second switch, and close the third switch; and
in a transmit mode, close the first switch, close the second switch, and open the third switch.

7. The apparatus of claim 6, wherein the control circuit is further configured to:
in the receive mode, cause the switching circuit to decouple the output of the power amplifier from the second inductor; and
in a transmit mode, cause the switching circuit to couple the output of the power amplifier to the second inductor.

8. The apparatus of claim 1, wherein the low-noise amplifier comprises:
a first transistor, wherein a gate of the first transistor is coupled to the input of the low-noise amplifier;
a source inductor coupled to a source of the first transistor; and
a second transistor, wherein a drain of the second transistor is coupled to the output of the low-noise amplifier, and a source of the second transistor is coupled to a drain of the first transistor.

9. The apparatus of claim 8, further comprising a second switch, wherein the source inductor and the second switch are coupled in series between the source of the first transistor and a ground.

10. The apparatus of claim 9, further comprising a control circuit configured to:
in a receive mode, open the first switch, close the second switch, and cause the switching circuit to decouple the output of the power amplifier from the second inductor; and
in a transmit mode, close the first switch, open the second switch, and cause the switching circuit to couple the output of the power amplifier to the second inductor.

11. The apparatus of claim 8, further comprising a bias circuit coupled to the gate of the first transistor and a gate of the second transistor, wherein the bias circuit is configured to:
in a receive mode, bias the gate of the first transistor at a first voltage, and bias the gate of the second transistor at a second voltage; and
in a transmit mode, couple the gate of the first transistor to a ground via a first resistor, and couple the gate of the second transistor to the ground via a second resistor.

12. The apparatus of claim 1, further comprising a mixer coupled to the second inductor.

13. The apparatus of claim 1, further comprising:
a resistor; and
a second switch, wherein the second switch and the resistor are coupled in series between a first terminal of the first inductor and a second terminal of the first inductor.

14. The apparatus of claim 13, further comprising a control circuit configured to:
in a receive mode, open the first switch, open the second switch, and cause the switching circuit to decouple the output of the power amplifier from the second inductor; and
in a transmit mode, close the first switch, close the second switch, and cause the switching circuit to couple the output of the power amplifier to the second inductor.

15. The apparatus of claim 1, further comprising:
a capacitor; and
a second switch, wherein the second switch and the capacitor are coupled in series between a first terminal of the first inductor and a second terminal of the first inductor.

16. The apparatus of claim 15, further comprising a control circuit configured to:
in a receive mode, open the first switch, close the second switch, and cause the switching circuit to decouple the output of the power amplifier from the second inductor; and
in a transmit mode, close the first switch, open the second switch, and cause the switching circuit to couple the output of the power amplifier to the second inductor.

17. The apparatus of claim 15, further comprising:
a resistor; and
a third switch, wherein the third switch and the resistor are coupled in series between the first terminal of the first inductor and the second terminal of the first inductor.

18. The apparatus of claim 1, further comprising:
a second low-noise amplifier having an input and an output;
a second switch coupled between the input of the second low-noise amplifier and the output of the second low-noise amplifier; and
a second transformer including a third inductor and a fourth inductor, wherein the third inductor is coupled to the output of the second low-noise amplifier;
wherein the switching circuit is coupled between the output of the power amplifier and the fourth inductor.

19. The apparatus of claim 18, further comprising a control circuit configured to:
in a first mode, cause the switching circuit to couple the output of the power amplifier to the second inductor and decouple the output of the power amplifier from the fourth inductor; and
in a second mode, cause the switching circuit to decouple the output of the power amplifier from the second inductor and couple the output of the power amplifier to the fourth inductor.

20. The apparatus of claim 19, wherein the control circuit is configured to:
in the first mode, close the first switch and open the second switch; and
in the second mode, open the first switch and close the second switch.

21. An apparatus, comprising:
a low-noise amplifier having an input and an output;
a first switch coupled between the input of the low-noise amplifier and the output of the low-noise amplifier;
a transformer including a first inductor, a second inductor, a third inductor, one or more first inductor switches coupled in series with the second inductor, and one or more second inductor switches coupled is series with the third inductor, wherein the first inductor is coupled to the output of the low-noise amplifier; and
a power amplifier having an input and an output, wherein the output of the power amplifier is coupled to the third inductor.

22. The apparatus of claim 21, further comprising a control circuit configured to:
in a receive mode, open the first switch, close the one or more first inductor switches, and open the one or more second inductor switches; and
in a transmit mode, close the first switch, open the one or more first inductor switches, and close the one or more second inductor switches.

23. The apparatus of claim 21, wherein:
the output of the power amplifier comprises a first output and a second output; and
the third inductor and the one or more second inductor switches are coupled in series between the first output and the second output of the power amplifier.

24. The apparatus of claim 21, wherein the output of the low-noise amplifier is coupled to a first terminal of the first inductor, and the apparatus further comprises:
a second switch coupled between a second terminal of the first inductor and a ground; and
a third switch coupled between the second terminal of the first inductor and a supply rail.

25. The apparatus of claim 24, further comprising a control circuit configured to:
in a receive mode, open the first switch, open the second switch, close the third switch, close the one or more first inductor switches, and open the one or more second inductor switches; and
in a transmit mode, close the first switch, close the second switch, open the third switch, open the one or more first inductor switches, and close the one or more second inductor switches.

26. The apparatus of claim 21, wherein the low-noise amplifier comprises:
a first transistor, wherein a gate of the first transistor is coupled to the input of the low-noise amplifier;
a second transistor, wherein a drain of the second transistor is coupled to the output of the low-noise amplifier, and a source of the second transistor is coupled to a drain of the first transistor;
a source inductor; and
a second switch, wherein the source inductor and the second switch are coupled in series between a source of the first transistor and a ground.

27. The apparatus of claim 26, further comprising a control circuit configured to:
in a receive mode, open the first switch, close the second switch, close the one or more first inductor switches, and open the one or more second inductor switches; and
in a transmit mode, close the first switch, open the second switch, open the one or more first inductor switches, and close the one or more second inductor switches.

28. A method for operating a wireless device, wherein the wireless device includes a low-noise amplifier having an input and an output, a switch coupled between the input of the low-noise amplifier and the output of the low-noise amplifier, and a power amplifier, the method comprising:
in a receive mode,
opening the switch;
receiving a first radio frequency (RF) signal at the input of the low-noise amplifier from an antenna; and
amplifying the first RF signal using the low-noise amplifier into an amplified RF signal; and
in a transmit mode,
closing the switch; and
routing a second RF signal from the power amplifier to the antenna through the switch.

29. The method of claim 28, wherein routing the second RF signal to the antenna through the switch comprises inductively coupling the second RF signal from the power amplifier to the switch using a transformer.

30. The method of claim 29, wherein the transformer includes an inductor, and the output of the low-noise amplifier is coupled to a first terminal of the inductor, the method comprising:
in the receive mode, coupling a second terminal of the inductor to a supply rail; and
in the transmit mode, coupling the second terminal of the inductor to a ground.
